(19) United States
(12) Patent Application Publication
(10) Pub. No.: US 2012/0304930 A1
(43) Pub. Date: Dec. 6, 2012

(54) CHAMBER EXHAUST IN-SITU CLEANING FOR PROCESSING APPARATUSES

(76) Inventors: Gregory Scott Verdict, Austin, TX (US); Kevin Griffin, Livermore, CA (US); Allen Gregory Fox, Sunnyvale, CA (US)

(21) Appl. No.: 13/485,590

(22) Filed: May 31, 2012

Related U.S. Application Data
(60) Provisional application No. 61/493,377, filed on Jun. 3, 2011.

(51) Int. Cl. C30B 25/14; B01D 29/52; B01D 46/42; B01D 53/74

(52) U.S. Cl. 118/715; 422/168; 55/344; 55/312

(57) ABSTRACT

Apparatuses and systems are disclosed for exhausting by-products from a processing chamber. In an embodiment, a dual exhaust system for removing by-products from a processing chamber includes a first exhaust line and a second exhaust line with each line having a pressure control valve and a particle trap for removing by-products. A portion of the first exhaust line may be coupled in parallel with the second exhaust line. The second exhaust line can be isolated from the first exhaust line and cleaned while the first exhaust line is removing by-products from the processing chamber or vice versa. In one embodiment, an exhaust system for removing by-products from a processing chamber includes an exhaust line and valves for removing the by-products. The valves are designed to operate at a high temperature such that the heated by-products are in a vapor phase while being removed through the exhaust line.

### RELATED APPLICATION

This application claims the benefit of U.S. Provisional Application No. 61/493,377, filed on Jun. 3, 2011, the entire contents of which are hereby incorporated by reference.

### FIELD

Embodiments of this invention relate to chamber exhaust in-situ cleaning for processing apparatuses.

### DESCRIPTION OF RELATED ART

Metal-organic vapor phase epitaxy (MOVPE) is one deposition methodology and hydride vapor phase epitaxy (HVPE) is an alternative epitaxial growth method of semiconductor materials (e.g., group III nitrides). In general, the HVPE process involves the reaction of one or more metallic halides with a hydride. For the growth of group III-nitride materials, typically metallic chlorides and ammonia (NH3) are used. The MOCVD and HVPE processes create chlorinated compounds such as NH4Cl and GaCl3 which are by-products of the light emitting diode (LED) manufacturing process. This material coats the entire process chamber exhaust system.

This material can build up on the pressure control valve and related hardware causing premature failure of the components. A particle trap is placed up stream of the pressure control valve in order to collect the by-products using cooling and filtering media. While this approach extends the life of the exhaust hardware, the particle trap clogs within a short time requiring frequent maintenance. Even with the particle trap protecting the exhaust hardware, by-products can still build up on the pressure control valve and related hardware because the particle trap is not 100% efficient in capturing the solid phase by-products or condensing the gas phase reactants. The formation of by-products (e.g., GaCl3, NH4Cl) produces fine powder in the exhaust hardware. The formation increases if residual moisture or HCl exists in the exhaust system. The choked flow of the pressure control valve leads to further condensation of residual reactants, which further clogs the pressure control valve.

### SUMMARY

Apparatuses and systems are disclosed for exhausting by-products from a processing chamber. In an embodiment, a dual exhaust system for removing by-products from a processing chamber includes a first exhaust line with a first pressure control valve and a first particle trap for removing by-products. The dual exhaust system also includes a second exhaust line coupled to the first exhaust line. The second exhaust line includes a second pressure control valve and a second particle trap for removing by-products. A portion of the first exhaust line may be coupled in parallel with the second exhaust line. The second exhaust line can be isolated from the first exhaust line and cleaned while the first exhaust line is removing by-products from the processing chamber. Alternatively, the first exhaust line can be cleaned while the second exhaust line is removing by-products from the processing chamber.

In one embodiment, an exhaust system for removing by-products from a processing chamber includes an exhaust line for removing the by-products, a pressure control valve, and an isolation valve. The pressure control valve and isolation valve are designed to operate at a high temperature up to approximately 300 degrees Celsius such that the heated by-products are in a vapor phase while being removed through the exhaust line. In this case, a trap is not needed for removing the by-products.

### BRIEF DESCRIPTION OF THE DRAWINGS

Embodiments of the present invention is illustrated by way of example, and not by way of limitation, in the figures of the accompanying drawings, in which:

FIG. 1 illustrates a schematic diagram of a dual exhaust system in accordance with one embodiment;

FIG. 2A illustrates a diagram of an exhaust system in one embodiment;

FIG. 2B illustrates a diagram of an exhaust system without a trap in one embodiment;

FIG. 3 illustrates a line graph that shows exhaust by-product data in accordance with one embodiment;

FIG. 4 illustrates a schematic diagram of a dual exhaust system in accordance with another embodiment;

FIG. 5A illustrates a diagram of an exhaust system with separate pumps and separate scrubbers in one embodiment;

FIG. 5B illustrates a diagram of an exhaust system with separate pumps and separate scrubbers in another embodiment;

FIG. 6A illustrates a cross-sectional view of a trap in accordance with one embodiment;

FIG. 6B illustrates an external view of a trap in accordance with one embodiment;

FIG. 7 illustrates an exhaust system with a down stream plasma unit (DPA) in accordance with one embodiment;

FIG. 8 illustrates a HVPE apparatus in accordance with one embodiment;

FIG. 9 illustrates a MOCVD apparatus in accordance with an embodiment;

FIG. 10 illustrates a cluster tool in accordance with one embodiment; and

FIG. 11 illustrates a cross-sectional view of a device in accordance with one embodiment.

### DETAILED DESCRIPTION

Apparatuses and systems are disclosed for exhausting by-products from a processing chamber. In an embodiment, a dual exhaust system for removing by-products from a processing chamber includes a first exhaust line and a second exhaust line with each line having a pressure control valve and a particle trap for removing by-products. A portion of the first exhaust line may be coupled in parallel with the second exhaust line. The second exhaust line can be isolated from the first exhaust line and cleaned while the first exhaust line is removing by-products from the processing chamber or vice versa.

In the following description, numerous details are set forth. It will be apparent, however, to one skilled in the art, that the present invention may be practiced without these specific details. In some instances, well-known methods and devices are shown in block diagram form, rather than in detail, to avoid obscuring the present invention. Reference throughout this specification to “an embodiment” means that a particular feature, structure, function, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not mutually exclusive.

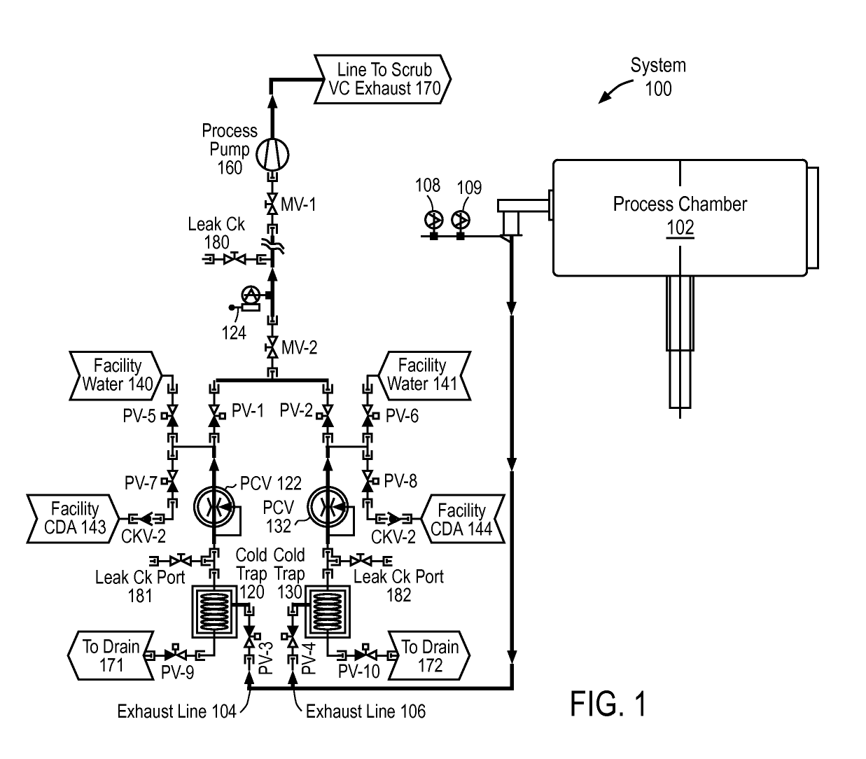

FIG. 1 illustrates a schematic diagram of a dual exhaust system in accordance with one embodiment. Ammonia Chloride and related chloride by-products are water soluble compounds. Water is used to clean the particle trap filters and process chamber exhaust components during the maintenance of the process chamber. The dual exhaust system 100 allows for the trap and valves to be cleaned in situ without removing the components and allows the process chamber 102 to continue to process substrates. The exhaust system 100 includes dual exhaust lines 104 and 106 with a parallel set of switching valves (e.g., PV-1, PV-3, PV-5, PV-7, PV-9 for exhaust line 104; PV-2, PV-4, PV-6, PV-8, PV-10 for exhaust line 106), manual or isolation valves (e.g., MV-1, MV-2), pressure control valves (e.g., 122, 132), particle cold traps 120 and 130, measurement devices (e.g., manometers 108 and 109, pressure monometer 124), and a chiller (not shown) coupled to the cold traps. For example, one set of hardware including line 106 is used to run the process chamber 102 with standard group III nitride materials (e.g, high temperature GaN) while the second set including the line 104 is cleaned. Alternatively, the line 104 can be used for exhaust while the line 106 is cleaned. If the process chamber utilization time is long enough to allow for cleaning and drying out, this concept could be used with a single set of exhaust components.

A normally closed (NC) valve PV-10 or PV-9 provides a water drain to atmospheric pressure. During the water fill process, facilities water is allowed to flow which is controlled by a NC isolation valve PV-5 or PV-6 shown in FIG. 1 into the volume that includes the particle trap and the pressure control valve until the entire volume is filled. The water supply valve is then shut off. The water remains in the volume until the ammonia chloride is dissolved from the particle trap filter media and the internal surfaces of the pressure control valve. The system 100 includes facility water inlets 140 and 141, facility CDA (Clean Dry Air) pressure inlets 143 and 144, leak check ports 180-182, and check valves ckv-2. A normally closed isolation valve PV-10 or PV-9 on the bottom of the trap is opened to allow the water to drain from the particle trap and volume between the main isolation valves. The CDA valve PV-7 or PV-8 is open to provide gas pressure to push the water to the scrubber or related location. The drain vent valve must remain open to allow the water to be pumped out and allow the CDA to flow long enough to dry down the residual water. The water is sent to the fab scrubber or approved location for disposal via outlets 171 or 172. Once the water is removed, the CDA valve is closed follow by the water drain valve.

The chiller typically operates at −30 to −10 degrees C. (e.g., −20 degrees C.). The temperature of the chiller is changed to a higher temperature (e.g., 40-60 degrees C.) and this fluid is pumped through the cooling coils of the particle trap. This higher temperature alone with CDA and/ or external heater jackets are used to drive off the remaining water in the particle trap. The water vapor is released through the drain valve. It is important to dry the trap prior to pumping the trap since excessive water in the exhaust system can cause premature clogging of the exhaust line. A venturi pump can also be used to remove the fluid from the particle trap. The fluid removal method is dependent on whether the chamber is top feed or bottom feed facilities connections and the delta pressure requirements for the fab chemical fluid neutralization system.

When the process sequence allows access to the process chamber pump 160, which is coupled to an outlet 170 that lead to the scrub vacuum exhaust, the isolation valves are opened to remove any remaining water in the clean trap. Heated N2 gas from the process chamber is introduced into the cleaned trap to drive out any remaining water vapor. The filter media may be pleated stainless steel. These filters are required to provide high surface area as compared to non-pleated cylindrical filters and the low density of the media allows for easy cleaning and dry out as compared to fiberglass media filters. Once the trap is dry, the upstream isolation valve is closed and the process chamber continues to run with the uncleaned trap (e.g., 130). Once the dirty trap approaches the point where it will become clogged, the trap is taken off line and the clean trap (e.g., 120) is used to run the process. Now, the dirty trap (e.g., 130) is run through the cleaning and drying process.

The trap internal volume and filter surface area is determined by the up time required for the trap between clean cycles. The volume and surface should be minimized to improve the cleaning and dry out process but it should be large enough to allow the process chamber to run uninterrupted by switching between the two parallel traps 120 and 130. The HVPE process typically generates much more by-product (e.g., 10 times more by-product) as compared to MOCVD. The HVPE process may require a set of larger capacity traps as compared to the MOCVD particle traps.

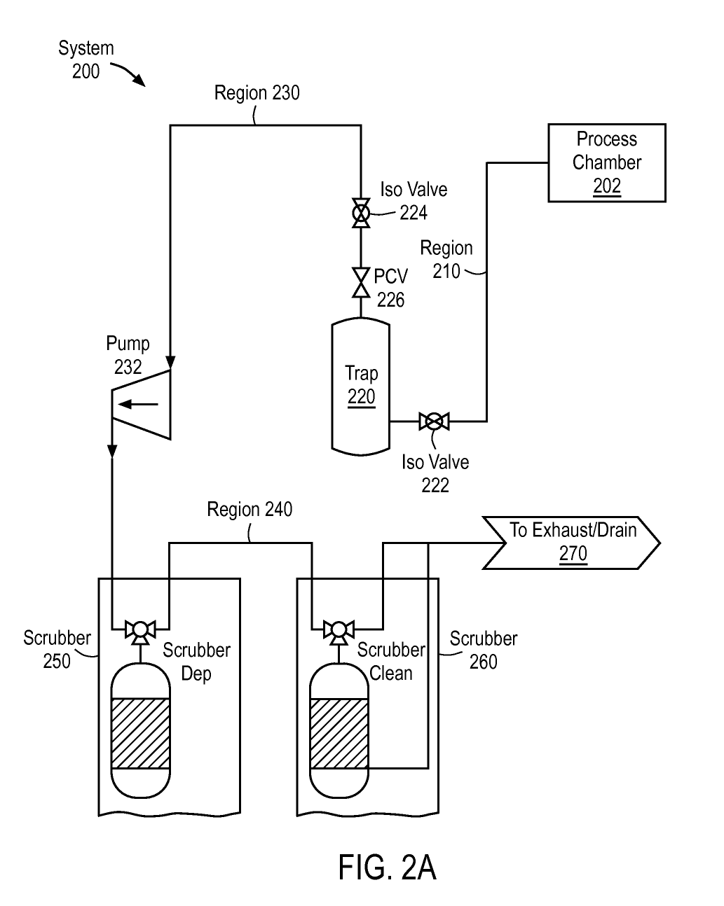

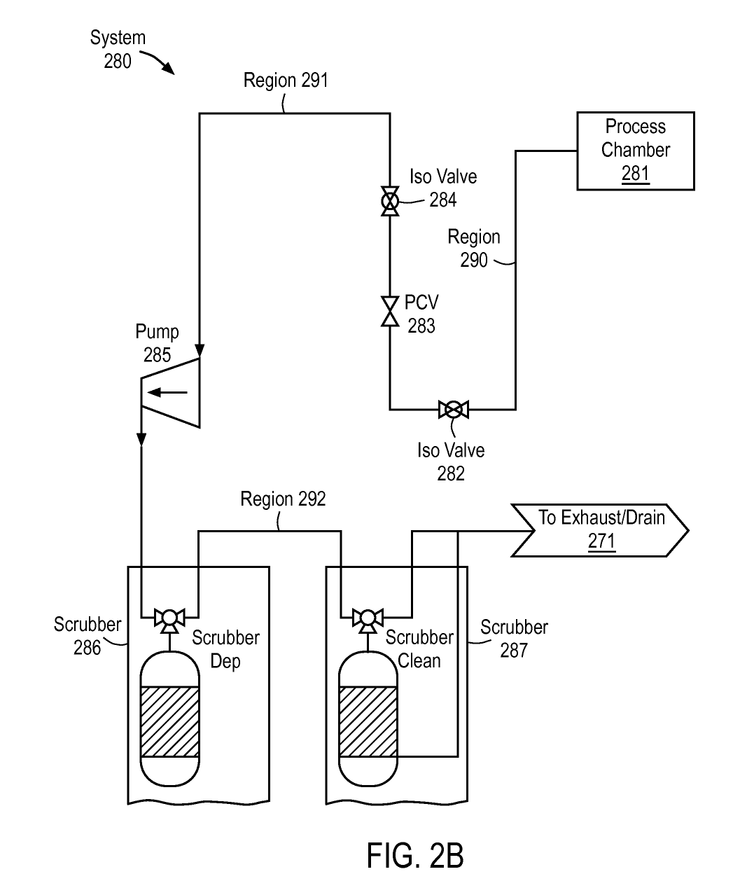

FIG. 2A illustrates a diagram of an exhaust system in one embodiment. The exhaust system 200 includes a process chamber 202, an exhaust line with exhaust line regions 210, 230, 240, isolation valves 222 and 224, a trap 220, a pressure control valve 226, a pump 232, scrubbers 250 and 260, and exhaust/drain 270 for processing of exhaust materials prior to leaving the manufacturing facility.

One set of operating conditions with a lower temperature (e.g., 150 degrees C.) can cause regions of the exhaust system to be become clogged. For example, the exhaust line region 210 may have a pressure of 300 Torr and a lower temperature (e.g., 150 degrees C.), the exhaust line region 230 may have a pressure of 20 Torr and a temperature of 150 degrees C., and the exhaust line region 240 may have a pressure of 755 Torr and a temperature of 150 degrees C. The trap 220 may trap by-products at −20 degrees C. with a low efficiency. These exhaust conditions can lead to clogging suspectibility or issues particularly if any leaks or cold spots occur. Preventive maintenance of the exhaust system may be required for every 250 um of deposition for certain materials (e.g., undoped GaN, n-type GaN).

In one embodiment, high temperature (e.g., a temperature up to 300 degrees C., a temperature up to 350 degrees C.) components reduce the likelihood of clogging issues. For example, high temperature pressure control valves and isolation valves can be used to reduce the build up of ammonia chloride on the valves. The valves can be made of nickel coated aluminum or stainless steel for temperatures up to approximately 300 degrees C.

FIG. 2B illustrates a diagram of an exhaust system without a trap in another embodiment. The exhaust system 280 includes a process chamber 281, an exhaust line with regions 290, 291, 292, isolation valves 282 and 284, a pressure control valve 283, a pump 285, scrubbers 286 and 287, and exhaust/drain 271.

In one embodiment, high temperature (e.g., a temperature up to 300 degrees C.) components in the exhaust system reduce the likelihood of clogging issues because the by-products remain in a vapor phase and a trap is not needed. For example, high temperature pressure control valves and isolation valves can used to reduce the build up of ammonia chloride on the valves. The valves can be made of nickel coated aluminum or stainless steel for temperature up to approximately 300 degrees C.

The particle traps if needed as illustrated in FIG. 1 and FIG. 2A can be removed and run with single or parallel pressure control valves. The water clean hardware will be used to clean the pressure control valves in situ. Being able to remove the particle trap depends on process chamber up time requirements and the pumps ability to survive a full load of ammonia chloride gas stream.

The exhaust line, before the isolation valves and pressure control valves, is heated to prevent clogging. Ideally, the gas stream is cooled and all ammonia chloride is condensed out in the particle trap area. As a result, the exhaust lines leading to the scrubber are not heated. Small micron filters and chillers are used to remove the ammonia chloride in the particle trap and pressure control valve volume. It is desirable to minimize the energy usage for the exhaust system in regards to heating and cooling. It is also desirable to reduce the hardware cost in regards to redundancy and excessive capacity/capability. However, process chamber up time between major maintenance cycles is the main variable to be maximized in a cost effective manner.

In another embodiment, this exhaust system design can be expanded to other particle trap applications where room temperature chemicals can dissolve process chamber by products. The chemicals would be injected in the closed volume including the particle trap and pressure control valve. This approach would extend the uptime for the system using a dual trap or single trap approach. This approach can be used for semiconductor, LED and solar process applications which require a particle trap and vacuum pump. This approach is a benefit to any process where the particle trap is the most frequently serviced item on the process chamber which impacts the uptime for the process chamber.

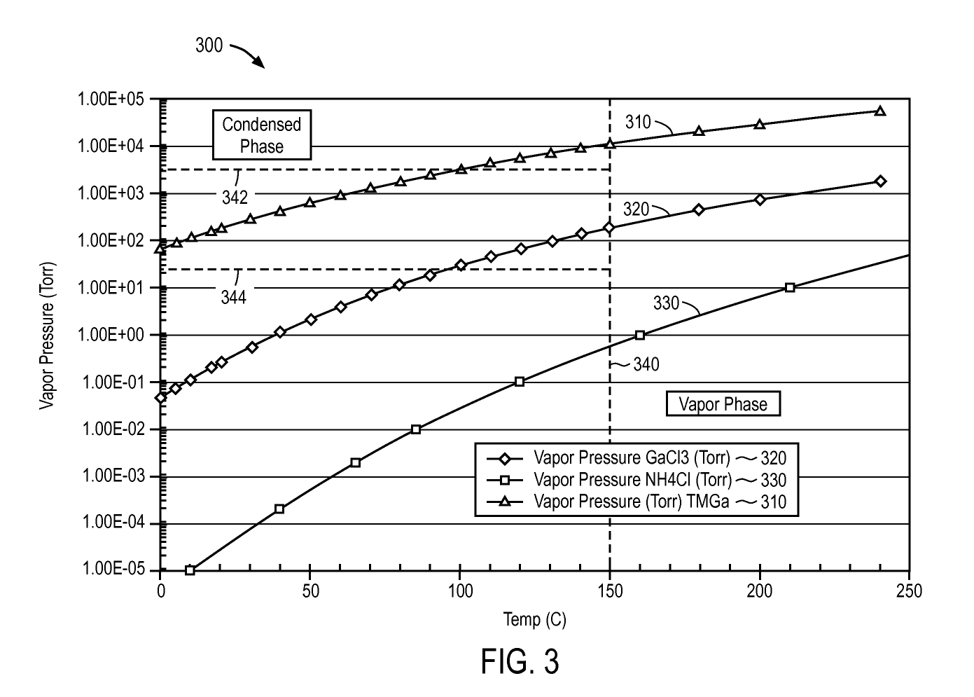

FIG. 3 illustrates a line graph that shows exhaust by-product data in accordance with one embodiment. The graph 300 illustrates vapor pressure in units of Torr on a vertical axis and temperature in units of degrees Celsius on a horizontal axis. The exhaust by-products include GaCl3, which is represented by line 320, ammonia chloride, NH4Cl, which is represented by line 330, and trimethylgallium, TMGa, which is represented by line 310. These by-products exist in a condensed phase for lower temperatures to the left of vertical line 340 and at higher pressure than line 310, 320, and 330 for the respective by-product. The vapor phase will exist at higher temperatures to the right of the line 340 and at lower pressures than lines 310, 320, and 330 for the respective by-product. All by-products illustrated in FIG. 3 will be in the vapor phase for higher temperatures to the right of the line 340 and at lower pressures than line 330. The line 342 represents a trap pressure of 300 Torr and the line 344 represents a post trap pressure of 25 Torr.

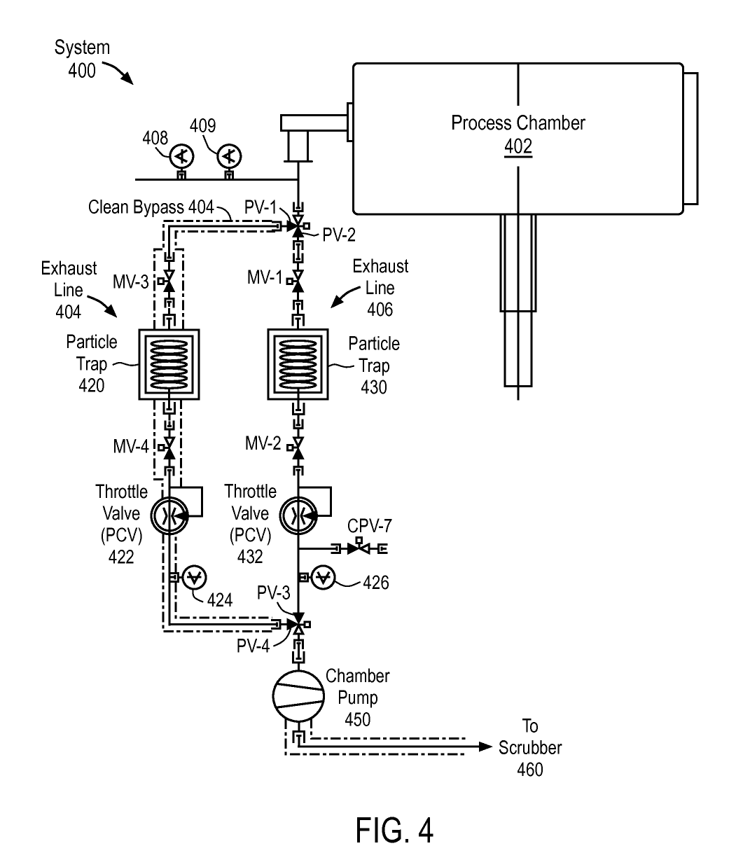

FIG. 4 illustrates a schematic diagram of a dual exhaust system in accordance with another embodiment. The dual exhaust system 400 allows for the by-products to be removed in separate exhaust lines in situ without removing the components and allows the process chamber 402 to continue to process substrates. The exhaust system 400 includes dual exhaust lines 404 and 406 with a parallel set of switching valves (e.g., PV-1, PV-2, PV-3, PV-4), manual or isolation valves (e.g., MV-1, MV-2, MV-3, MV-4), pressure control valves (e.g., 422, 432), particle traps 420 and 430, measurement devices (e.g., pressure/vacuum measurement devices, manometer 408, manometer 409, 424, 426), and a chiller (not shown) coupled to the particle traps. For example, one set of hardware including line 404 is used to remove one by-product (e.g, ammonia based, by-products generated from cleaning operations in the chamber) while the second set including the line 406 is used to remove another by-product (e.g, chlorine based, standard high temperature GaN by-products). In one embodiment, particle traps 420 and 430 are included in each exhaust line for removing the by-products. In another embodiment, for example at a high temperature (e.g., 300 degrees C.), the particle traps are not needed because the by-products will remain in a vapor phase. The exhaust lines are coupled to scrubbers 460. In an embodiment, the cleaning methods of the exhaust system 100 discussed in conjunction with FIG. 1 also apply to the exhaust system of FIG. 4 such as CDA and a venturi pump.

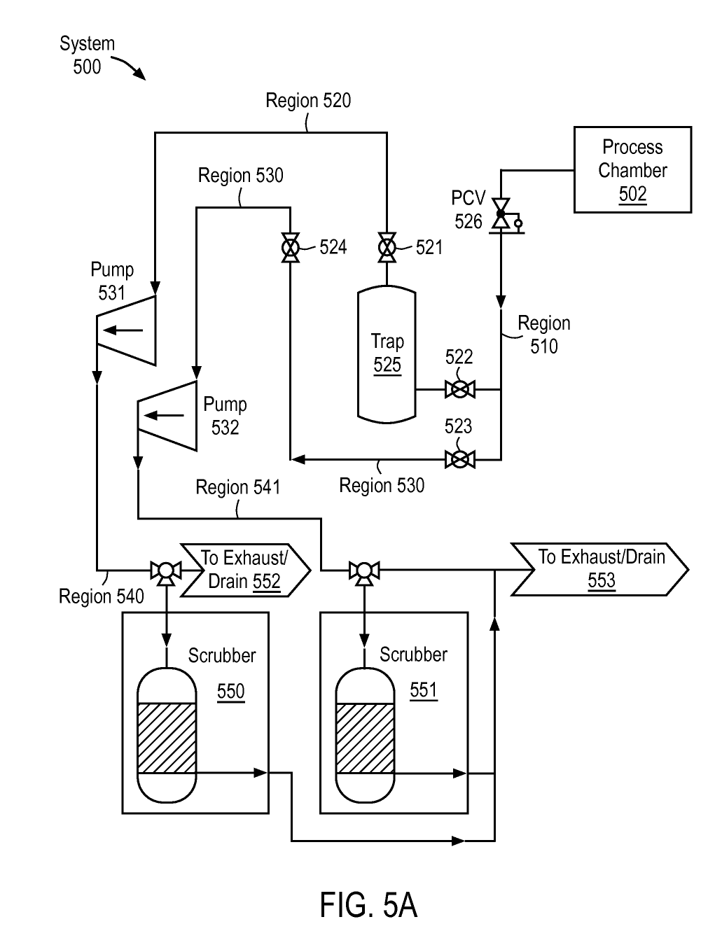

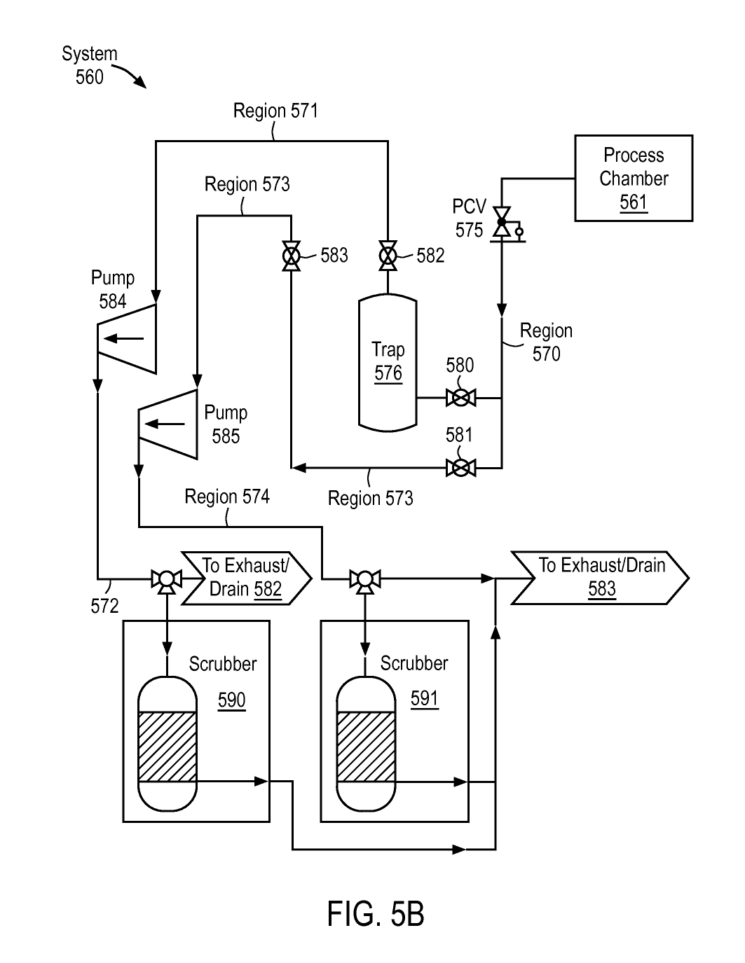

FIG. 5A illustrates a diagram of an exhaust system with separate pumps and separate scrubbers in one embodiment. The exhaust system 500 includes a process chamber 502, an exhaust line with exhaust line regions 510, 520, 530, 540-541, isolation valves 521-524, a trap 525, a pressure control valve 526, pump 531 and 532, scrubbers 550 and 551, and exhaust/drain 552 and 553 for processing of exhaust materials prior to leaving the manufacturing facility.

In one embodiment, the exhaust system is designed for a MOCVD chamber 502. One set of operating conditions with a lower temperature (e.g., 150 degrees C.) can cause regions of the exhaust system to be become clogged. For example, the exhaust line region 510 may have a pressure of 300 Torr and a higher temperature (e.g., 300 degrees C.), the exhaust line region 520 may have no active heating and it may be designed along with pump 531 for exhausting by-products of deposition operations from the chamber 502. The lines 530 and 541 may have no active heating and be designed along with pump 532 for exhausting by-products of cleaning operations (e.g., SiHi). Alternatively, the exhaust line regions 520, 530, and 540 may have some active heating (e.g., 150 degrees C.). The trap 525 may trap by-products of deposition operations at 20 degrees C.

FIG. 5B illustrates a diagram of an exhaust system with separate pumps and separate scrubbers in another embodiment. The exhaust system 560 includes a process chamber 561, an exhaust line with exhaust line regions 570-574, isolation valves 580-583, a trap 576, a pressure control valve 575, pumps 584 and 585, scrubbers 590 and 591, and exhaust/drain 592 and 593 for processing of exhaust materials prior to leaving the manufacturing facility.

In one embodiment, the exhaust system is designed for a HVPE chamber 561. One set of operating conditions with a lower temperature (e.g., 150 degrees C.) can cause regions of the exhaust system to be become clogged. For example, the exhaust line region 570 may have a pressure of 300 Torr and a higher temperature (e.g., 300 degrees C.), the exhaust line region 571 may have a pressure of 20 Torr and a lower temperature (e.g., 150 degrees C.) and it may be designed along with pump 584 for exhausting by-products of deposition operations from the chamber 561. The lines 573 and 574 may have no active heating and be designed along with pump 585 for exhausting by-products of cleaning operations (e.g., SiHi). Alternatively, the lines 573 and 574 may have active heating at a lower temperature (e.g., 150 degrees C.). The trap 576 may trap by-products of deposition operations at −20 degrees C.

In one embodiment, high temperature (e.g., a temperature up to 300 degrees C., a temperature up to 350 degrees C.) components in the exhaust system reduce the likelihood of clogging issues. For example, high temperature pressure control valves and isolation valves can be used to reduce the build up of ammonia chloride on the valves. The valves can be made of nickel coated aluminum or stainless steel for temperatures up to approximately 300 degrees C.

In one embodiment, a low pressure chamber cleaning increases a preventive maintenance period for a pressure control valve (PCV) in an exhaust system. For example, a HVPE chamber cleaning after every GaN deposition with a total Cl2 flow on a Ga Boat of 77 liters, pressure of 100 Torr, heater on the PCV, can allow an estimated total GaN deposition of approximately 250 um. Embodiments of the present disclosure allow the preventive maintenance (PM) period to be extending such that GaN can be deposited to a thickness of 1500 um before needing PM.

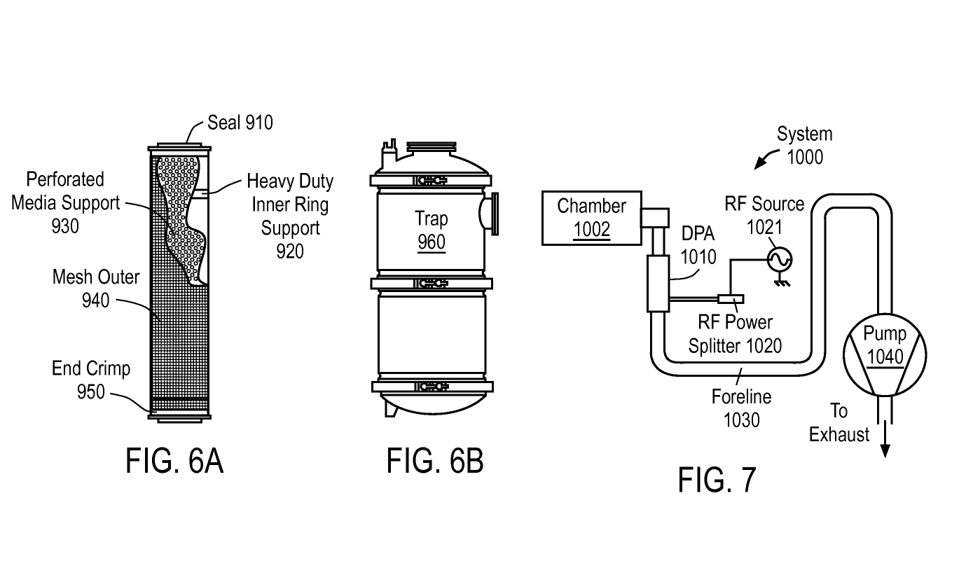

FIG. 6A illustrates a cross-sectional view of a trap in accordance with one embodiment. The trap 900 includes a gasket seal 910, a heavy duty inner ring support 920, a perforated media support 940, and an end crimp 950. FIG. 6B illustrates an external view of a trap 960 in accordance with one embodiment.

FIG. 7 illustrates an exhaust system 1000 with a down stream plasma unit (DPA) in accordance with one embodiment. A processing chamber 1002 is coupled to the DPA 1010, which is powered by RF source 1021 via RF power splitter 1020. A foreline 1030 carries by-products from the DPA to the pump 1040. In one embodiment, the DPA destructs ammonia into N2 and H2.

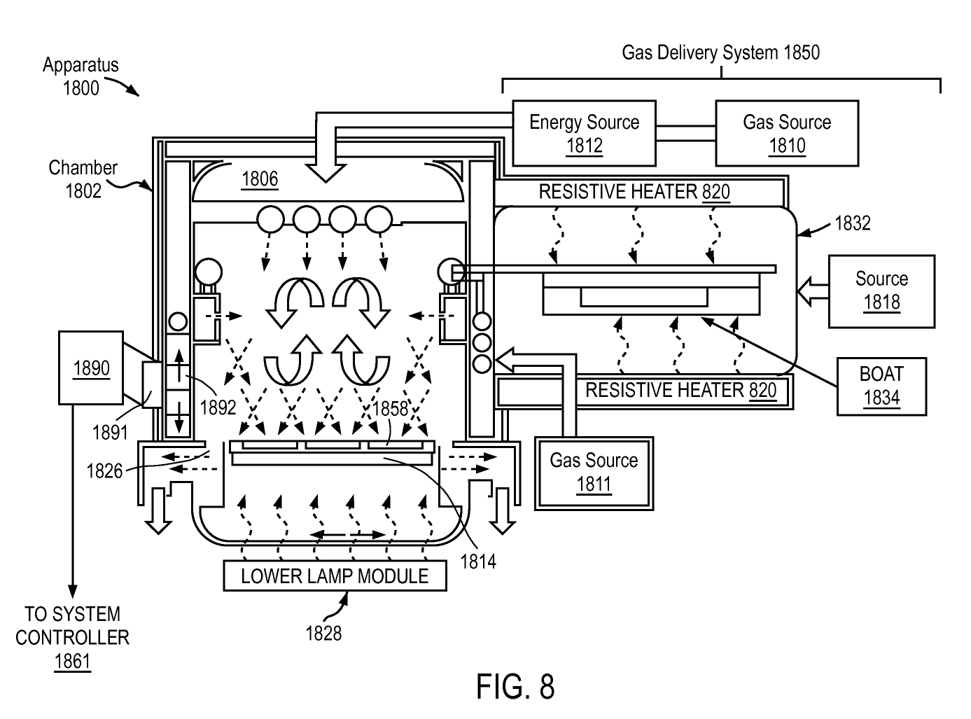

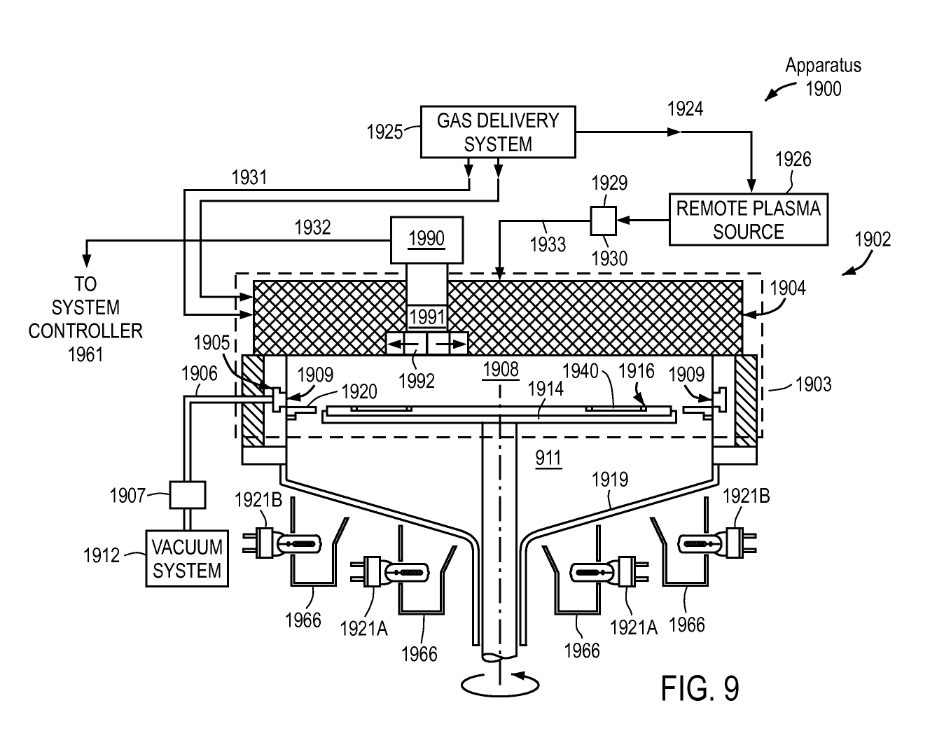

Turning now to FIGS. 8 and 9, the exhaust system is described in conjunction with exemplary processing systems or apparatuses. A substrate 1858 including a GaN base layer, in one embodiment, is provided to an epitaxial deposition chamber. The epitaxy chamber may be as depicted in FIGS. 8 and 9, or any other commercially available chamber.

The substrate is heated during the recipe stabilization period. For example, a HVPE apparatus 1800 depicted in FIG. 8, includes a shutter 1892 disposed between the window 1891 and the chamber 1802. In an exemplary embodiment, a pyrometer 1890 is disposed external to the window 1891 and upon the shutter 1892 opening, temperature readings may begin being sampled. Similarly, in FIG. 9 an MOCVD apparatus configured with in-situ temperature measurement hardware including the pyrometer 1990, window 1991 and shutter 1992 is illustrated.

Referring first to FIG. 8, a processing gas from a first gas source 1810 is delivered to the chamber 1802 through a gas distribution showerhead 1806. In one embodiment, the gas source 1810 may include a nitrogen containing compound. In another embodiment, the gas source 1810 may include ammonia. In one embodiment, an inert gas such as helium or diatomic nitrogen may be introduced as well either through the gas distribution showerhead 1806 or through the walls of the chamber 1802 from gas source 1811. An energy source 1812 may be disposed between the gas source 1810 and the gas distribution showerhead 1806. In one embodiment, the energy source 1812 may include a heater. The energy source 1812 may break up the gas from the gas source 1810, such as ammonia, so that the nitrogen from the nitrogen containing gas is more reactive.

To react with the gas from the first source 1810, precursor material may be delivered from one or more second sources 1818. The precursor may be delivered to the chamber 1802 by flowing a reactive gas over and/or through the precursor in the precursor source 1818. In one embodiment, the reactive gas may include a chlorine containing gas such as diatomic chlorine. The chlorine containing gas may react with the precursor source to form a chloride. In order to increase the effectiveness of the chlorine containing gas to react with the precursor, the chlorine containing gas may snake through the boat area 1834 in the region 1832 and be heated with the resistive heater 1820. By increasing the residence time that the chlorine containing gas is snaked through the region 1832, the temperature of the chlorine containing gas may be controlled. By increasing the temperature of the chlorine containing gas, the chlorine may react with the precursor faster. In other words, the temperature is a catalyst to the reaction between the chlorine and the precursor.

In order to increase the reactiveness of the precursor, the precursor may be heated by a resistive heater 820 within the region 1832 in a boat. The chloride reaction product may then be delivered to the chamber 1802 where it mixes with the nitrogen containing gas to form a nitride layer on the substrate 1816 that is disposed on a susceptor 1814. In one embodiment, the susceptor 1814 may include silicon carbide. The nitride layer may include gallium nitride for example. The other reaction products, such as nitrogen and chlorine, are exhausted through an exhaust 1826 to an exhaust system described in the present disclosure.

A gas delivery system 1850 may include any of the components (e.g., sources 1810-1812, 1818) described in FIG. 8 that are needed for delivering chemicals to the HVPE apparatus 1800.

Turning to FIG. 9, a schematic cross-sectional view of an MOCVD chamber which can be utilized in embodiments of the invention is depicted. The MOCVD apparatus 1900 shown in FIG. 9 includes a chamber 1902, a gas delivery system 1925, a remote plasma source 1926, a vacuum system 1912, and a system controller 1961. The chamber 1902 includes a chamber body 1903 that encloses a processing volume 1908. A showerhead assembly 1904 is disposed at one end of the processing volume 1908, and a substrate carrier 1914 is disposed at the other end of the processing volume 1908. A lower dome 1919 is disposed at one end of a lower volume 911, and the substrate carrier 1914 is disposed at the other end of the lower volume 911. The substrate carrier 1914 is shown in process position, but may be moved to a lower position where, for example, the substrates 1940 may be loaded or unloaded. An exhaust ring 1920 may be disposed around the periphery of the substrate carrier 1914 to help prevent deposition from occurring in the lower volume 911 and also help direct exhaust gases from the chamber 1902 to exhaust ports 1909.

The lower dome 1919 may be made of transparent material, such as high-purity quartz, to allow light to pass through for radiant heating of the substrates 1940. The radiant heating may be provided by a plurality of inner lamps 1921A and outer lamps 1921 B disposed below the lower dome 1919. Reflectors 1966 may be used to help control chamber 1902 exposure to the radiant energy provided by inner and outer lamps 1921 A, 1921 B. Additional rings of lamps may also be used for finer temperature control of the substrates 1940.

Returning to FIG. 9, the substrate carrier 1914 may include one or more recesses 1916 within which one or more substrates 1940 may be disposed during processing. The substrate carrier 1914 may carry one or more substrates 1940. In one embodiment, the substrate carrier 1914 carries eight substrates 1940. It is to be understood that more or less substrates 1940 may be carried on the substrate carrier 1914. Typical substrates 1940 may include sapphire, silicon carbide (SiC), silicon, or gallium nitride (GaN). It is to be understood that other types of substrates 1940, such as glass substrates 1940, may be processed. Substrate 1940 size may range from 50 mm-300 mm in diameter or larger. The substrate carrier 1914 size may range from 200 mm-750 mm. The substrate carrier 1914 may be formed from a variety of materials, including SiC or SiC-coated graphite. It is to be understood that substrates 1940 of other sizes may be processed within the chamber 1902 and according to the processes described herein. The showerhead assembly 1904, as described herein, may allow for more uniform deposition across a greater number of substrates 1940 and/or larger substrates 1940 than in traditional MOCVD chambers, thereby increasing throughput and reducing processing cost per substrate 1940.

The substrate carrier 1914 may rotate about an axis during processing. In one embodiment, the substrate carrier 1914 may be rotated at about 2 RPM to about 100 RPM. In another embodiment, the substrate carrier 1914 may be rotated at about 30 RPM. Rotating the substrate carrier 1914 aids in providing uniform heating of the substrates 1940 and uniform exposure of the processing gases to each substrate 1940.

The plurality of inner and outer lamps 1921 A, 1921 B may be arranged in concentric circles or zones (not shown), and each lamp zone may be separately powered. In one embodiment, one or more temperature sensors, such as pyrometers (not shown), may be disposed within the showerhead assembly 1904 to measure substrate 1940 and substrate carrier 1914 temperatures, and the temperature data may be sent to a controller (not shown) which can adjust power to separate lamp zones to maintain a predetermined temperature profile across the substrate carrier 1914. In another embodiment, the power to separate lamp zones may be adjusted to compensate for precursor flow or precursor concentration non-uniformity. For example, if the precursor concentration is lower in a substrate carrier 1914 region near an outer lamp zone, the power to the outer lamp zone may be adjusted to help compensate for the precursor depletion in this region.

The inner and outer lamps 1921A, 1921B may heat the substrates 1940 to a temperature of about 400 degrees Celsius to about 1200 degrees Celsius. It is to be understood that embodiments of the invention are not restricted to the use of arrays of inner and outer lamps 1921A, 1921B. Any suitable heating source may be utilized to ensure that the proper temperature is adequately applied to the chamber 1902 and substrates 1940 therein. For example, in another embodiment, the heating source may include resistive heating elements (not shown) which are in thermal contact with the substrate carrier 1914.

A gas delivery system 1925 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 1902. Different gases, such as precursor gases, carrier gases, purge gases, cleaning/etching gases or others may be supplied from the gas delivery system 1925 to separate supply lines 1931, 1932, and 1933 to the showerhead assembly 1904. The supply lines 1931, 1932, and 1933 may include shut-off valves and mass flow controllers or other types of controllers to monitor and regulate or shut off the flow of gas in each line.

A conduit 1929 may receive cleaning/etching gases from a remote plasma source 1926. The remote plasma source 1926 may receive gases from the gas delivery system 1925 via supply line 1924, and a valve 1930 may be disposed between the showerhead assembly 1904 and remote plasma source 1926. The valve 1930 may be opened to allow a cleaning and/or etching gas or plasma to flow into the showerhead assembly 1904 via supply line 1933 which may be adapted to function as a conduit for a plasma. In another embodiment, MOCVD apparatus 1900 may not include remote plasma source 1926 and cleaning/etching gases may be delivered from gas delivery system 1925 for non-plasma cleaning and/or etching using alternate supply line configurations to shower head assembly 1904.

The remote plasma source 1926 may be a radio frequency or microwave plasma source adapted for chamber 1902 cleaning and/or substrate 1940 etching. Cleaning and/or etching gas may be supplied to the remote plasma source 1926 via supply line 1924 to produce plasma species which may be sent via conduit 1929 and supply line 1933 for dispersion through showerhead assembly 1904 into chamber 1902. Gases for a cleaning application may include fluorine, chlorine or other reactive elements.

In another embodiment, the gas delivery system 1925 and remote plasma source 1926 may be suitably adapted so that precursor gases may be supplied to the remote plasma source 1926 to produce plasma species which may be sent through showerhead assembly 1904 to deposit CVD layers, such as III-V films, for example, on substrates 1940.

A purge gas (e.g., nitrogen) may be delivered into the chamber 1902 from the showerhead assembly 1904 and/or from inlet ports or tubes (not shown) disposed below the substrate carrier 1914 and near the bottom of the chamber body 1903. The purge gas enters the lower volume 911 of the chamber 1902 and flows upwards past the substrate carrier 1914 and exhaust ring 1920 and into multiple exhaust ports 1909 which are disposed around an annular exhaust channel 1905.

An exhaust conduit 1906 connects the annular exhaust channel 1905 to a vacuum system 1912 which includes a vacuum pump (not shown). The chamber 1902 pressure may be controlled using a valve system 1907 which controls the rate at which the exhaust gases are drawn from the annular exhaust channel 1905.

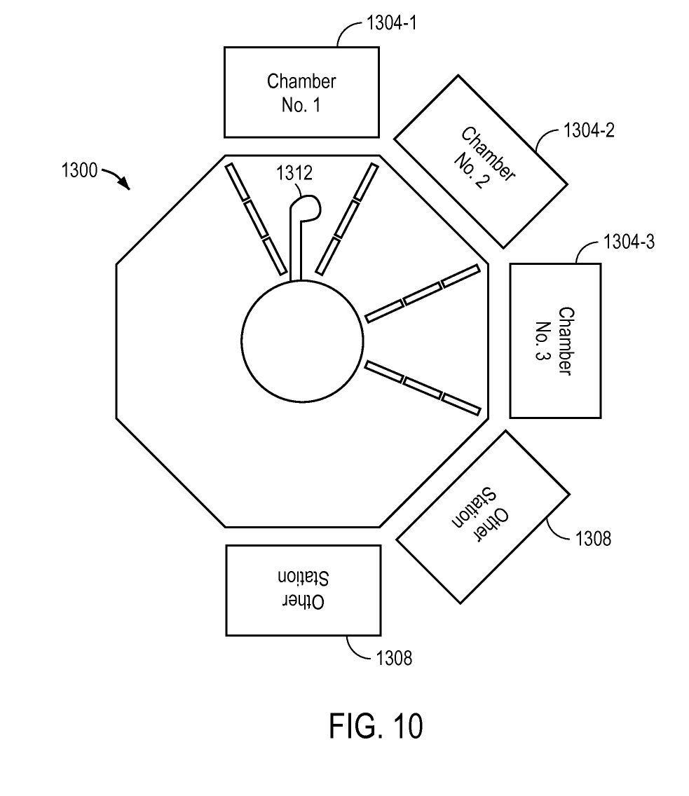

The HVPE apparatus 1800 and the MOCVD apparatus 1900 may be used in a processing system which includes a cluster tool that is adapted to process substrates and analyze the results of the processes performed on the substrate. The physical structure of the cluster tool is illustrated schematically in FIG. 10. In this illustration, the cluster tool 1300 includes three processing chambers 1304-1, 1304-2, 1304-3, and two additional stations 1308, with robotics 1312 adapted to effect transfers of substrates between the chambers 1304 and stations 1308. The structure permits the transfers to be effected in a defined ambient environment, including under vacuum, in the presence of a selected gas, under defined temperature conditions, and the like. The cluster tool is a modular system including multiple chambers that perform various processing operations that are used to form an electronic device. The cluster tool may be any platform known in the art that is capable of adaptively controlling a plurality of process modules simultaneously. Exemplary embodiments include an Opus™ AdvantEdge™ system or a Centura™ system, both commercially available from Applied Materials, Inc. of Santa Clara, Calif.

For a single chamber process, layers of differing composition are grown successively as different steps of a growth recipe executed within the single chamber. For a multiple chamber process, layers in a III-V or II-VI structure are grown in a sequence of separate chambers. For example, an undoped/nGaN layer may be grown in a first chamber, a MQW structure grown in a second chamber, and a pGaN layer grown in a third chamber.

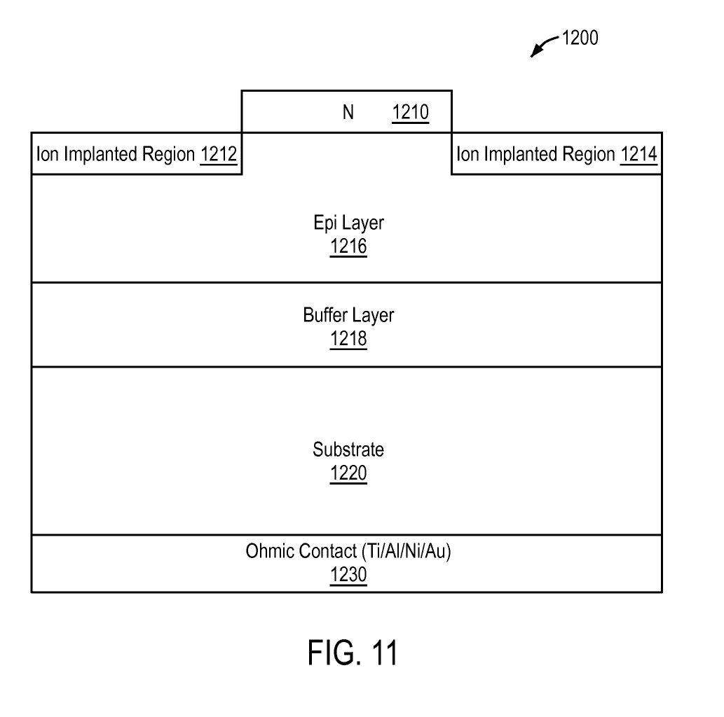

FIG. 11 illustrates a cross-sectional view of a power electronics device in accordance with one embodiment. The power electronic device 1200 may include an N type region 1210 (e.g., electrode), ion implanted regions 1212 and 1214, an epitaxial layer 1216 (e.g., N type GaN epi layer with a thickness of 4 microns), a buffer layer (e.g., N+ GaN buffer layer with a thickness of 2 microns), a substrate 1220 (e.g., N+ bulk GaN substrate, silicon substrate), and an ohmic contact (e.g., Ti/Al/Ni/Au). The device 1200 may include one or more layers of GaN disposed on a GaN substrate or a silicon substrate. The device (e.g., power IC, power diode, power thyristor, power MOSFET, IGBT, GaN HEMT transistor) may be used for switches or rectifiers in power electronics circuits and modules.

It is to be understood that the above description is intended to be illustrative, and not restrictive. Many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration. Accordingly, the specification and drawings are to be regarded in an illustrative sense rather than a restrictive sense.

What is claimed is:

1. A dual exhaust system for removing by-products from a processing chamber, comprising:
a first exhaust line with a first pressure control valve and a first particle trap for removing by-products; and
a second exhaust line coupled to the first exhaust line, the second exhaust line having a second pressure control valve and a second particle trap for removing by-products.

2. The dual exhaust system of claim 1, wherein a portion of the first exhaust line is coupled in parallel with the second exhaust line.

3. The dual exhaust system of claim 1, wherein the first and second exhaust lines each further comprise at least one isolation valve.

4. The dual exhaust system of claim 3, wherein the second exhaust line is a bypass clean line when isolated from the first exhaust line with the isolation valve of the second exhaust line.

5. The dual exhaust system of claim 4, wherein the bypass clean line does not receive by-products when isolated while the first exhaust line does receive by-products from the processing chamber.

6. The dual exhaust system of claim 1, wherein the second particle trap and the second pressure control valve are cleaned when the bypass clean line does not receive by-products.

7. The dual exhaust system of claim 1, further comprising:
a chamber pump coupled to the first and second exhaust lines.

8. An exhaust system for removing by-products from a processing chamber, comprising:
an exhaust line for removing the by-products; and
a pressure control valve coupled to the exhaust line, the pressure control valve is designed to operate at a high temperature up to approximately 300 degrees Celsius.

9. The exhaust system of claim 8, further comprising:
an isolation valve coupled to the exhaust line, the isolation valve is designed to operate at a high temperature up to approximately 300 degrees Celsius.

10. The exhaust system of claim 9, wherein by-products are removed through the exhaust line while in a vapor phase.

11. The exhaust system of claim 10, wherein the exhaust line does not need a trap for removing by-products because the by-products are in the vapor phase.

12. The exhaust system of claim 11, wherein the high temperature pressure control valve and isolation valve reduce the build up of ammonia chloride on the valves.

13. The exhaust system of claim 8, further comprising:
a down stream plasma chamber coupled to the exhaust line, the down stream plasma chamber to destruct an ammonia by-product into nitrogen gas and hydrogen gas.

14. A processing system for removing by-products from a processing chamber, comprising:
a processing chamber;
a first exhaust line with a first valve to isolate a first by-product; and
a second exhaust line coupled in parallel to the first exhaust line, the second exhaust line with a second valve to isolate a second by-product.

15. The processing system of claim 14, wherein the first exhaust line further comprises a first pump and the second exhaust line further comprises a second pump.

16. The processing system of claim 15, wherein the first exhaust line further comprises a first trap and the second exhaust line further comprises a second trap.

17. The processing system of claim 16, wherein the first and second pumps each further comprise water injection for self-cleaning of the first and second traps, respectively.

18. The processing system of claim 14, wherein the processing chamber is a Metal-organic vapor phase epitaxy (MOVPE) chamber.

19. The processing system of claim 14, further comprising:
at least one scrubber coupled to the first and second exhaust lines, the at least one scrubber to remove the by-products.

20. The processing system of claim 14, wherein the processing chamber is a hydride vapor phase epitaxy (HVPE) chamber.
